(19) United States
(12) Patent Application Publication
(10) Pub. No.: US 2025/0197990 A1
(43) Pub. Date: Jun. 19, 2025

(54) FILM FORMATION METHOD AND FILM FORMATION DEVICE

(71) Applicant: Tokyo Electron Limited, Minato-ku, Tokyo (JP)

(72) Inventors: Shuji AZUMO, Nirasaki City, Yamanashi (JP); Yumiko KAWANO, Nirasaki City, Yamanashi (JP); Takashi FUSE, Nirasaki City, Yamanashi (JP)

(21) Appl. No.: 18/837,904

(22) PCT Filed: Feb. 1, 2023
(86) PCT No.: PCT/JP2023/003176

§ 371 Date: Aug. 13, 2024

(30) Foreign Application Priority Data
Feb. 14, 2022 (JP) 2022-020187

(51) Int. Cl. C23C 16/04; C23C 16/06; C23C 16/56

(52) U.S. Cl. CPC C23C 16/042; C23C 16/06; C23C 16/56

(57) ABSTRACT

A film formation method includes: (A) preparing a substrate having a first film and a second film formed in different regions of a surface of the substrate, the second film made of a material different from the first film; (B) supplying a gas of carboxylic acid or phosphonic acid to the surface of the substrate to selectively form a self-assembled monolayer on a surface of the second film relative to a surface of the first film; and (C) forming a target film on the surface of the first film while inhibiting formation of the target film on the surface of the second film using the self-assembled monolayer, after (B), wherein (C) includes (C1) supplying a precursor gas for the target film to the surface of the substrate, and (C2) supplying a gas of carboxylic acid or phosphonic acid as an oxidizing gas to the surface of the substrate.

### TECHNICAL FIELD

The present disclosure relates to a film formation method and a film formation device.

### BACKGROUND

Patent Document 1 describes a film formation method in which a self-assembled monolayer (SAM) is used to inhibit the formation of a target film on a portion of a substrate surface and form the target film on another portion of the substrate surface. Patent Document 1 describes that a thiol-based compound or a silane-based compound is used as a precursor of the SAM.

### PRIOR ART DOCUMENT

### Patent Document

Patent Document 1: Japanese Laid-Open Publication No. 2021-108335

The present disclosure provides some embodiments of a technique capable of improving the blocking performance of a SAM.

### SUMMARY

The film formation method according to one embodiment of the present disclosure includes the following (A) to (C). (A) A substrate having a first film and a second film formed in different regions of a surface of the substrate is prepared, the second film made of a material different from the first film. (B) A gas of carboxylic acid or phosphonic acid is supplied to the surface of the substrate to selectively form a self-assembled monolayer on a surface of the second film relative to a surface of the first film. After (B), (C) a target film is formed on the surface of the first film while inhibiting formation of the target film on the surface of the second film using the self-assembled monolayer. (C) includes (Ca) supplying a precursor gas for the target film to the surface of the substrate, and (Cb) supplying a gas of carboxylic acid or phosphonic acid as an oxidizing gas to the surface of the substrate.

According to the present disclosure, it is possible to improve the blocking performance of a SAM.

### BRIEF DESCRIPTION OF DRAWINGS

FIG. 1 is a flowchart showing a film formation method according to one embodiment.

FIG. 2A is a diagram showing an example of step S1.

FIG. 2B is a diagram showing an example of step S2.

FIG. 2C is a diagram showing an example of step S3.

FIG. 3A is a diagram showing an example of step S41.

FIG. 3B is a diagram showing an example of step S42.

FIG. 3C is a diagram showing an example of step S5.

FIG. 4 is a flowchart showing a film formation method according to a modification.

FIG. 5 is a plan view showing a film formation device according to one embodiment.

FIG. 6 is a sectional view showing an example of the first processor shown in FIG. 5.

### DETAILED DESCRIPTION

Hereinafter, embodiments of the present disclosure will be described with reference to the drawings. In the drawings, the same or corresponding components are denoted by like reference numerals, and the description thereof may be omitted.

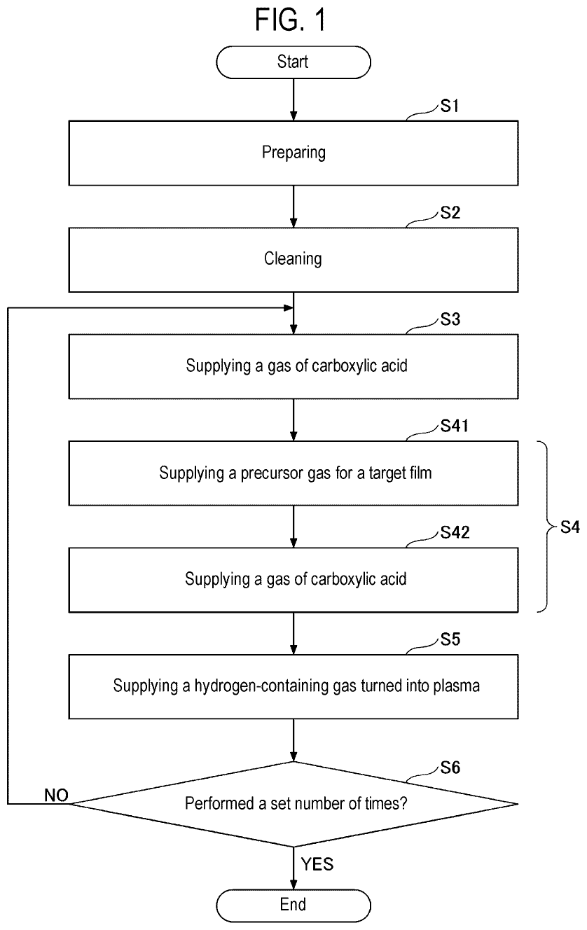

A film formation method according to one embodiment will be described with reference to FIGS. 1 to 3. The film formation method includes, for example, steps S1 to S6 shown in FIG. 1. If the film formation method includes at least steps S1 and S3 to S4, and it may not include, for example, steps S2 and S5 to S6. The film formation method may also include steps other than steps S1 to S6 shown in FIG. 1.

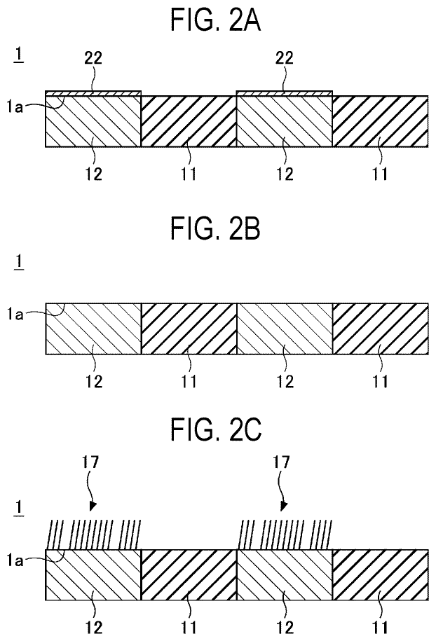

Step S1 in FIG. 1 includes preparing a substrate 1 as shown in FIG. 2A. The substrate 1 includes a base substrate (not shown). The base substrate is, for example, a silicon wafer, a compound semiconductor wafer, or a glass substrate.

The substrate 1 includes an insulating film 11 and a conductive film 12 in different regions of a substrate surface 1a. The substrate surface 1a is, for example, an upper surface of the substrate 1. The insulating film 11 and the conductive film 12 are formed on a base substrate. Another functional film may be formed between the base substrate and the insulating film 11, or between the base substrate and the conductive film 12. The insulating film 11 is an example of a first film, and the conductive film 12 is an example of a second film. The materials of the first film and the second film are not particularly limited.

The insulating film 11 is, for example, an interlayer insulating film. The interlayer insulating film is preferably a low dielectric constant (low-k) film. The insulating film 11 is, but is not limited to, a SiO film, a SiN film, a SiOC film, a SiON film, or a SiOCN film. In this regard, the SiO film means a film containing silicon (Si) and oxygen (O). The atomic ratio of Si to O in the SiO film is usually 1:2, but is not limited to 1:2. The SiN film, the SiOC film, the SiON film, or the SiOCN film contains respective elements in a similar manner, and the stoichiometric ratios thereof are not limited. The insulating film 11 has a recess on the substrate surface 1a. The recess is a trench, a contact hole, or a via hole.

The conductive film 12 fills, for example, the recess of the insulating film 11. The conductive film 12 is, for example, a metal film. The metal film is, for example, a Cu film, a Co film, a Ru film, or a W film. The conductive film 12 may be a cap film. In other words, a second conductive film (not shown) may be filled in the recess of the insulating film 11, and the second conductive film may be covered by the conductive film 12. The second conductive film is formed of a metal different from that of the conductive film 12.

Although not shown, the substrate 1 may further have a third film formed on the substrate surface 1a. The third film is, for example, a barrier film. The barrier film is formed between the insulating film 11 and the conductive film 12 to suppress metal diffusion from the conductive film 12 to the insulating film 11. The barrier film is not particularly limited, but is, for example, a TaN film or a TiN film. As used herein, the term TaN film means a film containing tantalum (Ta) and nitrogen (N). The atomic ratio of Ta and N in the TaN film is usually 1:1, but is not limited to 1:1. Similarly, the term TiN film means that it contains respective elements, and the stoichiometric ratio thereof is not particularly limited.

Although not shown, the substrate 1 may further include a fourth film formed on the substrate surface 1a. The fourth film is, for example, a liner film. The liner film is formed between the conductive film 12 and the barrier film. The liner film is formed on the barrier film to assist in the formation of the conductive film 12. The conductive film 12 is formed on the liner film. The liner film is not particularly limited, but is, for example, a Co film or a Ru film.

As shown in FIG. 2B, step S2 in FIG. 1 includes cleaning the substrate surface 1a. Contaminants 22 (see FIG. 2A) present on the substrate surface 1a can be removed. The contaminants 22 include at least one of, for example, a metal oxide or an organic substance. The metal oxide is an oxide formed by, for example, a reaction between the conductive film 12 and the atmosphere, and is a so-called natural oxide film. The organic substance is, for example, a deposit containing carbon, which adheres during the processing of the substrate 1. The cleaning of the substrate surface 1a may be performed by either a dry process or a wet process.

For example, step S2 includes supplying a cleaning gas to the substrate surface 1a. The cleaning gas may be turned into plasma to improve the efficiency of removing the contaminants 22. The cleaning gas includes, for example, a reducing gas such as an H₂ gas or the like. The reducing gas removes an oxide such as natural oxide film or the like, and an organic substance.

An example of the processing conditions in step S2 is shown below.
H₂ gas flow rate: 200 sccm to 10,000 sccm
Ar gas flow rate: 20 sccm to 2,000 sccm
Power supply frequency for plasma generation: 400 kHz to 40 MHz
Power for plasma generation: 50 W to 1,000 W
Processing time: 10 sec to 600 sec
Processing temperature (substrate temperature): 100 degrees C. to 250 degrees C.
Processing pressure: 100 Pa to 2,000 Pa

As shown in FIG. 2C, step S3 in FIG. 1 includes selectively forming a SAM 17 on the surface of the conductive film 12 relative to the surface of the insulating film 11. Step S3 may include supplying a gas of carboxylic acid, which is a precursor of the SAM 17.

Carboxylic acid contains a carboxy group (COOH group) and is represented by the general formula “R—COOH”. R is, for example, a hydrocarbon group or a hydrocarbon group in which at least a portion of hydrogen has been substituted with fluorine. Carboxylic acid is more likely to be chemically adsorbed to the surface of the conductive film 12 than to the surface of the insulating film 11. Therefore, the SAM 17 is selectively formed on the surface of the conductive film 12.

The carboxylic acid includes, for example, at least one selected from the group consisting of CF₃(CF₂)₂COOH, CF₃COOH, C₆H₅COOH, and CH₃(CH₂),COOH (where n is an integer of 2 to 10). Hereinafter, CF₃ (CF₂)₂COOH is also referred to as PFBA (perfluorobutyric acid).

Carboxylic acid is more likely to be chemically adsorbed to the Ru film surface than thiol-based compounds. Therefore, when the conductive film 12 is a Ru film, the density of the SAM 17 can be improved. Furthermore, carboxylic acid can form a SAM 17 that is more resistant to high temperatures than thiol-based compounds. Therefore, the processing temperature in step S4 (forming a target film) described later can be set to a high temperature. An example of the processing conditions in step S3 is shown below.
PFBA gas flow rate: 10 sccm to 100 sccm
Processing time: 30 sec to 600 sec
Processing pressure: 100 Pa to 300 Pa
Processing temperature: 100 degrees C. to 250 degrees C.
Phosphonic acid may be used instead of carboxylic acid. Phosphonic acid is represented by the general formula “R—P(═O)(OH)₂”. R is, for example, a hydrocarbon group in which at least a portion of hydrogen has been substituted with fluorine. Just like carboxylic acid, phosphonic acid is more likely to be chemically adsorbed to the surface of the conductive film 12 than to the surface of the insulating film 11. Therefore, a SAM 17 is selectively formed on the surface of the conductive film 12.

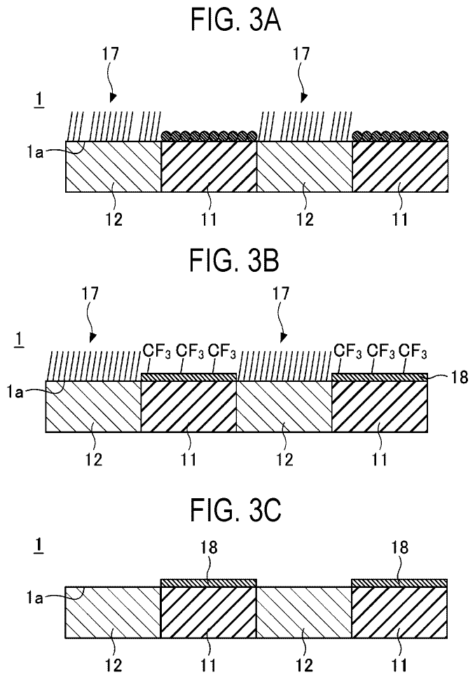

As shown in FIGS. 3A and 3B, step S4 in FIG. 1 includes forming a target film 18 on the surface of the insulating film 11 while inhibiting the formation of the target film 18 on the surface of the conductive film 12 using the SAM 17. The target film 18 is, for example, an insulating film, and is formed on the insulating film 11.

The target film 18 is not particularly limited, but may be, for example, an AlO film, a SiO film, a ZrO film, or a HfO film. As used herein, the term AlO film means a film containing aluminum (Al) and oxygen (O). The atomic ratio of Al to O in the AlO film is usually 2:3, but is not limited to 2:3. Similarly, the SiO film, ZrO film, or HfO film contains respective elements, and the stoichiometric ratios thereof are not particularly limited.

The target film 18 is formed, for example, by an ALD (Atomic Layer Deposition) method. When an oxide film is formed as the target film 18 by the ALD method, a precursor gas for the target film 18 and an oxidizing gas are alternately supplied to the substrate surface 1a. The precursor gas for the target film 18 contains, for example, a metal element or a metalloid element oxidized by the oxidizing gas.

The target film 18 may be formed by a chemical vapor deposition (CVD) method. When an oxide film is formed as the target film 18 by the CVD method, a precursor gas for the target film 18 and an oxidizing gas are simultaneously supplied to the substrate surface 1a.

The following describes a case where the target film 18 is formed by the ALD method. As shown in FIG. 1, step S4 includes steps S41 and S42.

Step S41 includes supplying a precursor gas for the target film 18 to the substrate surface 1a. Since the SAM 17 is formed on the surface of the conductive film 12 as shown in FIG. 3A, the precursor gas is selectively adsorbed onto the surface of the insulating film 11.

Step S42 may include supplying a gas of carboxylic acid as an oxidizing gas to the substrate surface 1a. The gas of carboxylic acid oxidizes the metal element or the metalloid element contained in the precursor gas for the target film 18, thereby forming the target film 18 as shown in FIG. 3B. The gas of carboxylic acid can also replenish the SAM 17 on the surface of the insulating film 11 during the formation of the target film 18, thereby improving the blocking performance of the SAM 17.

The same gas of carboxylic acid may be used in step S42 and step S3. By using the same gas of carboxylic acid, it is possible to reduce the number of types of gas used can be reduced, and the number of individual pipes provided for respective gases. As will described below, different gases of carboxylic acid may be used in step S42 and step S3.

As the oxidizing gas, a gas of phosphonic acid may be used instead of the gas of carboxylic acid. Just like the gas of carboxylic acid, the gas of phosphonic acid can also form the target film 18 by oxidizing the metal element or the metalloid element contained in the precursor gas for the target film 18. In addition, just like the gas of carboxylic acid, the gas of phosphonic acid can also replenish the SAM 17 on the surface of the insulating film 11 during the formation of the target film 18, and can improve the blocking performance of the SAM 17.

The same gas of phosphonic acid may be used in step S42 and step S3. By using the same gas of phosphonic acid, it is possible to reduce the number of types of gas used, and the number of individual pipes provided for respective gases. As will described later, different gases of phosphonic acid may be used in step S42 and step S3.

An example of the process conditions in step S4 is shown below. In the process conditions shown below, the TMA (trimethylaluminum) gas is a precursor gas for an AlO film.

### Step S41

TMA gas flow rate: 50 sccm
Processing time: 0.1 sec to 2 sec
Processing temperature: 100 degrees C. to 250 degrees C.
Processing pressure: 133 Pa to 1,200 Pa.

### Step S42

PFBA gas flow rate: 50 sccm to 200 sccm
Processing time: 0.5 sec to 2 sec
Processing temperature: 100 degrees C. to 250 degrees C.
Processing pressure: 133 Pa to 1,200 Pa.

The amount of gas of carboxylic acid or phosphonic acid supplied in step S42 may be less than the amount of gas of carboxylic acid or phosphonic acid supplied in step S3. This can reduce the amount of residues of carboxylic acid or phosphonic acid adhering to the target film 18 in step S42. The residue is, for example, a hydrocarbon group or a hydrocarbon group in which at least a portion of hydrogen has been substituted with fluorine. The amount of gas supplied is calculated by integrating the flow rate per unit time over time.

As shown in FIG. 3C, in step S5 of FIG. 1, a hydrogen-containing gas turned into plasma is supplied to the substrate surface 1a to remove the residues of carboxylic acid or phosphonic acid adhering to the target film 18 in step S42. This can improve the film quality of the target film 18.

The hydrogen-containing gas used in step S5 is, for example, an H₂ gas, an H₂O gas, an NH₃ gas, or an N₂H₄ gas. A hydrocarbon gas such as a CH₄ gas or the like may also be used. If the amount of residue is small, step S5 is not necessary.

Although not shown, in step S42, the blocking performance of the SAM 17 may not be perfect, and the peripheral edge of the target film 18 may protrude laterally beyond the surface of the insulating film 11 to cover a portion of the surface of the conductive film 12. In this case, step S5 may include etching the peripheral edge of the target film 18 as described below. Thus, the opening of the target film 18 can be enlarged, and the wiring resistance of the substrate 1 can be reduced.

When the SAM 17 contains fluorine, active species containing fluorine and carbon are generated by the reaction between the hydrogen-containing gas turned into plasma and the SAM 17. The active species thus generated etches the peripheral edge of the target film 18. The peripheral edge of the target film 18 becomes a volatile compound, which is removed by exhaust. The volatile compound contains fluorine or contains fluorine and carbon.

As described above, the active species containing fluorine and carbon are generated by the reaction between the hydrogen-containing gas turned into plasma and the SAM 17. Accordingly, the active species are generated only in the vicinity of the SAM 17. Therefore, although the peripheral edge of the target film 18 is etched, the center of the target film 18 (the portion deposited on the surface of the insulating film 11) is not etched. Only the peripheral edge of the target film 18 can be selectively removed.

An example of the processing conditions in step S5 is shown below.
H₂ gas flow rate: 200 sccm to 10,000 sccm
Ar gas flow rate: 20 sccm to 2,000 sccm
Power supply frequency for plasma generation: 400 kHz to 40 MHz
Power for plasma generation: 50 W to 1,000 W
Processing time: 10 sec to 600 sec
Processing temperature (substrate temperature): 100 degrees C. to 250 degrees C.
Processing pressure: 100 Pa to 2,000 Pa

The hydrogen-containing gas turned into plasma not only removes the residue adhering to the target film 18, but also removes the SAM 17. Therefore, after step S5, step S3 is performed again before performing step S4 again (see FIG. 1). By repeatedly performing a cycle including steps S3, S41, S42 and S5, a target film 18 having an excellent film quality and a large thickness can be selectively formed on the surface of the insulating film 11. The thickness of the target film 18 formed in one cycle is on the order of one atom to several atoms, and is less than 1 nm.

Steps S3, S41, S42 and S5 are repeatedly performed, for example, in the same processing container. Steps S3, S41, S42 and S5 are repeatedly performed by supplying various gases into the same processing container in a desired order. Between adjacent steps, there may be a step of discharging various gases remaining in the processing container by supplying an inert gas such as an argon gas or the like into the processing container.

Step S6 in FIG. 1 includes checking whether steps S3, S41, S42 and S5 have been performed a set number of times. If the number of execution times has not reached the set number of times (if “NO” in step S6), steps S3, S41, S42 and S5 are performed again as the film thickness of the target film 18 has not reached the target film thickness. On the other hand, if the number of execution times has reached the set number of times (if “YES” in step S6), the processing is terminated as the film thickness of the target film 18 has reached the target film thickness. The set number of times in step S6 is set according to the target film thickness of the target film 18, and is, for example, 20 to 80 times.

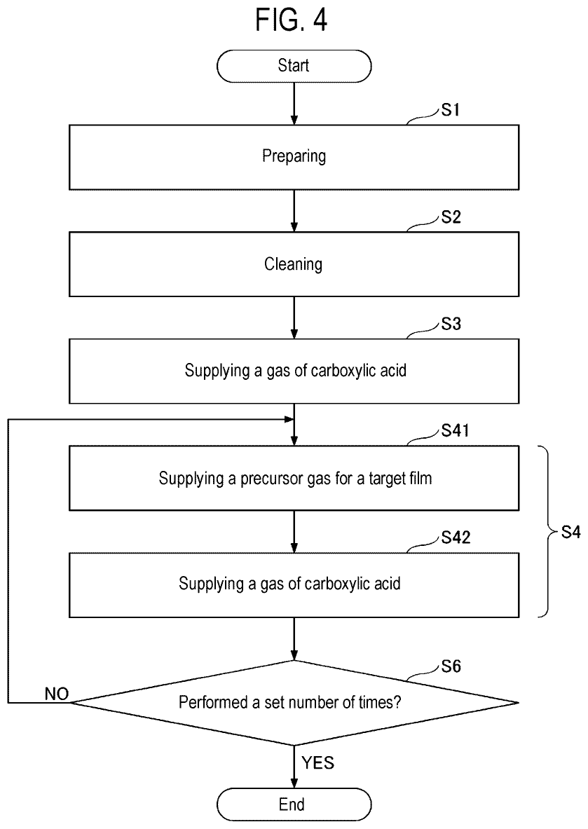

Next, a film formation method according to a modification will be described with reference to FIG. 4. If there is little residue of carboxylic acid or phosphonic acid remaining on the target film 18 in step S42, the quality of the target film 18 is good even if step S5 in FIG. 1 is not performed. Furthermore, if step S5 is not performed, the SAM 17 is not removed. Therefore, there is no need to perform step S3 again before performing step S4 again.

As shown in FIG. 4, in the film formation method of this modification, a cycle including steps S41 and S42 is repeatedly performed to selectively form a target film 18 having a desired thickness on the surface of the insulating film 11. The thickness of the target film 18 formed in one cycle is on the order of one atom to several atoms, and is less than 1 nm.

The gas of carboxylic acid or phosphonic acid used in step S42 may have a shorter straight chain than the gas of carboxylic acid or phosphonic acid used in step S3. The straight chain refers to a portion in which carbon atoms are connected in a straight line without branching or forming a ring. The longer the straight chain, the better the blocking performance of the SAM 17, but the more residue will adhere to the target film 18.

As described above, if the gas of carboxylic acid or phosphonic acid used in step S42 has a shorter straight chain than the gas of carboxylic acid or phosphonic acid used in step S3, it is possible to replenish the SAM 17 on the surface of the insulating film 11 during the formation of the target film 18, and to reduce the amount of carboxylic acid or phosphonic acid residue adhering to the target film 18. The content of this modification is also applicable to the film formation method shown in FIG. 1, i.e., the film formation method that does not perform step S5.

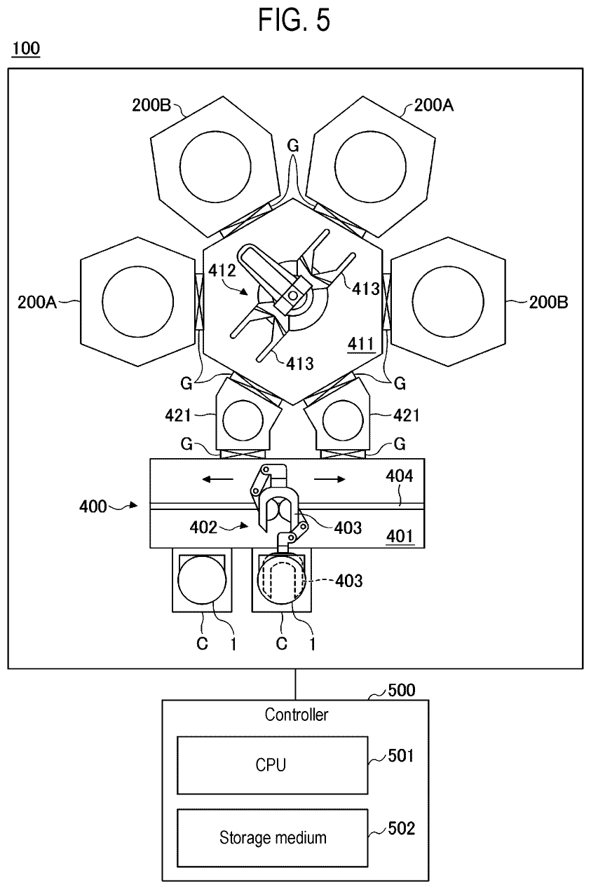

Next, a film formation device 100 for performing the above-described film formation method will be described with reference to FIG. 5. As shown in FIG. 5, the film formation device 100 includes a first processor 200A, a second processor 200B, a transfer portion 400, and a controller 500. The first processor 200A performs step S2 in FIG. 1. The second processor 200B repeatedly performs a cycle including steps S3 to S5 in FIG. 1. The first processor 200A and the second processor 200B have the same structure. Therefore, all of steps S2 to S5 in FIG. 1 can be performed only by the first processor 200A. The first processor 200A and the second processor 200B may have different structures. The transfer portion 400 transfers the substrate 1 to the first processor 200A and the second processor 200B. The controller 500 controls the first processor 200A, the second processor 200B, and the transfer portion 400.

The transfer portion 400 includes a first transfer chamber 401 and a first transfer mechanism 402. The internal atmosphere of the first transfer chamber 401 is an air atmosphere. The first transfer mechanism 402 is provided inside the first transfer chamber 401. The first transfer mechanism 402 includes an arm 403 that holds the substrate 1, and travels along a rail 404. The rail 404 extends in the arrangement direction of carriers C.

The transfer portion 400 also includes a second transfer chamber 411 and a second transfer mechanism 412. The internal atmosphere of the second transfer chamber 411 is a vacuum atmosphere. The second transfer mechanism 412 is provided inside the second transfer chamber 411. The second transfer mechanism 412 includes an arm 413 that holds the substrate 1. The arm 413 is arranged to be movable in the vertical and horizontal directions and rotatable around a vertical axis. The first processor 200A and the second processor 200B are connected to the second transfer chamber 411 via different gate valves G.

Furthermore, the transfer portion 400 has a load lock chamber 421 between the first transfer chamber 401 and the second transfer chamber 411. The internal atmosphere of the load lock chamber 421 can be switched between a vacuum atmosphere and an air atmosphere by a pressure adjustment mechanism (not shown). This allows the inside of the second transfer chamber 411 to be constantly maintained in a vacuum atmosphere. In addition, it is possible to prevent a gas from flowing from the first transfer chamber 401 into the second transfer chamber 411. Gate valves G are provided between the first transfer chamber 401 and the load lock chamber 421 and between the second transfer chamber 411 and the load lock chamber 421.

The controller 500 is, for example, a computer, and includes a CPU (Central Processing Unit) 501 and a storage medium 502 such as a memory or the like. The storage medium 502 stores programs that control various processes executed in the film formation device 100. The controller 500 controls the operation of the film formation device 100 by having the CPU 501 execute the programs stored in the storage medium 502. The controller 500 controls the first processor 200A, the second processor 200B, and the transfer portion 400 to perform the above-described film formation method.

Next, the operation of the film formation device 100 will be described. First, the first transfer mechanism 402 takes out the substrate 1 from the carrier C, transfers the taken-out substrate 1 to the load lock chamber 421, and moves out of the load lock chamber 421. Next, the internal atmosphere of the load lock chamber 421 is switched from an air atmosphere to a vacuum atmosphere. Thereafter, the second transfer mechanism 412 takes out the substrate 1 from the load lock chamber 421, and transfers the taken-out substrate 1 to the first processor 200A.

Next, the first processor 200A performs step S2. Thereafter, the second transfer mechanism 412 takes out the substrate 1 from the first processor 200A and transfers the taken-out substrate 1 to the second processor 200B. During this time, the atmosphere around the substrate 1 can be maintained as a vacuum atmosphere to suppress oxidation of the substrate 1.

Next, the second processor 200B repeatedly performs a cycle including steps S3 to S5. Thereafter, the second transfer mechanism 412 takes out the substrate 1 from the second processor 200B, transfers the taken-out substrate 1 to the load lock chamber 421, and moves out of the load lock chamber 421. The internal atmosphere of the load lock chamber 421 is then switched from a vacuum atmosphere to an air atmosphere. Thereafter, the first transfer mechanism 402 takes out the substrate 1 from the load lock chamber 421, and stores the taken-out substrate 1 in the carrier C. Then, the processing of the substrate 1 is completed.

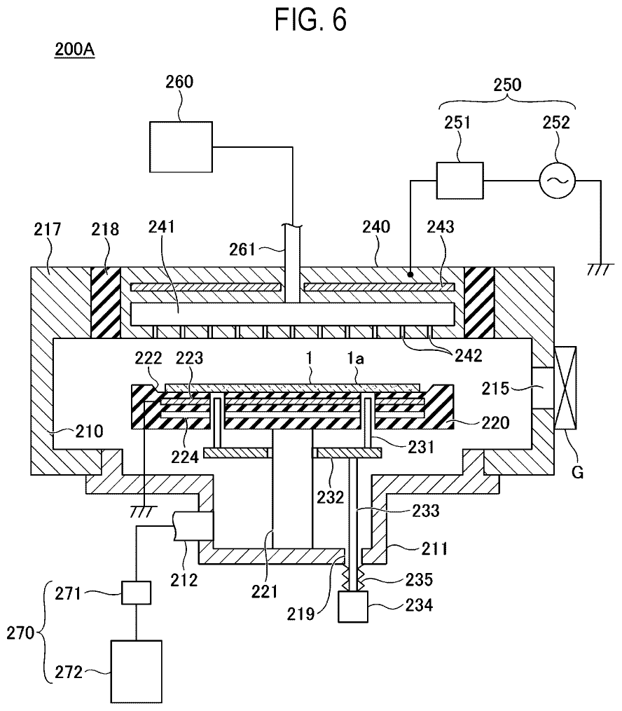

Next, the first processor 200A will be described with reference to FIG. 6. The second processor 200B has the same configuration as the first processor 200A, and therefore will not be illustrated or described.

The first processor 200A includes a substantially cylindrical airtight processing container 210. An exhaust chamber 211 is provided in the central portion of the bottom wall of the processing container 210. The exhaust chamber 211 has, for example, a substantially cylindrical shape that protrudes downward. An exhaust pipe 212 is connected to the exhaust chamber 211, for example, at a side surface of the exhaust chamber 211.

An exhaust source 272 is connected to the exhaust pipe 212 via a pressure controller 271. The pressure controller 271 includes a pressure adjustment valve such as a butterfly valve or the like. The exhaust pipe 212 is configured so that the inside of the processing container 210 can be depressurized by the exhaust source 272. The pressure controller 271 and the exhaust source 272 constitute a gas exhaust mechanism 270 that exhausts a gas inside the processing container 210.

A transfer port 215 is provided on the side surface of the processing container 210. The transfer port 215 is opened and closed by a gate valve G. The substrate 1 is loaded and unloaded between the processing container 210 and the second transfer chamber 411 (see FIG. 5) via the transfer port 215.

A stage 220, which is a holder for holding the substrate 1, is provided in the processing container 210. The stage 220 holds the substrate 1 horizontally with the substrate surface 1a facing upward. The stage 220 is formed in a substantially circular shape in a plan view, and is supported by a support member 221. A substantially circular recess 222 for mounting the substrate 1 having a diameter of, for example, 300 mm is formed on the surface of the stage 220. The recess 222 has an inner diameter slightly larger than the diameter of the substrate 1. The depth of the recess 222 is set to be, for example, substantially the same as the thickness of the substrate 1. The stage 220 is made of a ceramic material such as aluminum nitride (AlN) or the like. The stage 220 may also be made of a metal material such as nickel (Ni) or the like. Instead of the recess 222, a guide ring for guiding the substrate 1 may be provided on the peripheral edge portion of the surface of the stage 220.

For example, a grounded lower electrode 223 is embedded in the stage 220. A heating mechanism 224 is embedded below the lower electrode 223. The heating mechanism 224 heats the substrate 1 mounted on the stage 220 to a set temperature by being supplied with electric power from a power supplier (not shown) based on a control signal from a controller 500 (see FIG. 5). When the entire stage 220 is made of metal, the entire stage 220 functions as a lower electrode. Therefore, the lower electrode 223 does not need to be embedded in the stage 220. The stage 220 is provided with a plurality of (e.g., three) lift pins 231 for holding and lifting the substrate 1 mounted on the stage 220. The material of the lift pins 231 may be, for example, ceramics such as alumina (Al₂O₃), or quartz. The lower ends of the lift pins 231 are installed on a support plate 232. The support plate 232 is connected to an elevating mechanism 234 provided outside the processing container 210 via an elevating shaft 233.

The elevating mechanism 234 is installed, for example, at the bottom of the exhaust chamber 211. A bellows 235 is provided between the elevating mechanism 234 and an opening 219 for the elevating shaft 233 formed in the bottom surface of the exhaust chamber 211. The support plate 232 may have a shape in which the support plate 232 can be raised and lowered without interfering with the support member 221 of the stage 220. The lift pins 231 are configured to be freely raised and lowered by the elevating mechanism 234 between above the surface of the stage 220 and below the surface of the stage 220.

A gas supplier 240 is provided on the ceiling wall 217 of the processing container 210 via an insulating member 218. The gas supplier 240 constitutes an upper electrode and faces the lower electrode 223. A radio-frequency power source 252 is connected to the gas supplier 240 via a matching device 251. By supplying radio-frequency power of 450 kHz to 100 MHz from the radio-frequency power source 252 to the upper electrode (gas supplier 240), a radio-frequency electric field is generated between the upper electrode (gas supplier 240) and the lower electrode 223, and capacitively coupled plasma is generated. A plasma generator 250 that generates plasma includes a matching device 251 and a radio-frequency power source 252. The plasma generator 250 may generate other plasma such as inductively coupled plasma in addition to the capacitively coupled plasma. In a process that does not generate plasma, it is not necessary for the gas supplier 240 to constitute the upper electrode, and the lower electrode 223 is also not necessary.

The gas supplier 240 includes a hollow gas supply chamber 241. A multiple number of holes 242 for dispersing and supplying a processing gas into the processing container 210 are arranged, for example, evenly, on the bottom surface of the gas supply chamber 241. A heating mechanism 243 is embedded, for example, above the gas supply chamber 241 in the gas supplier 240. The heating mechanism 243 is heated to a set temperature by being supplied with electric power from a power supplier (not shown) based on a control signal from the controller 500.

A gas supply mechanism 260 is connected to the gas supply chamber 241 via a gas supply path 261. The gas supply mechanism 260 supplies a gas used in at least one of steps S2 to S5 in FIG. 1 to the gas supply chamber 241 via the gas supply path 261. Although not shown, the gas supply mechanism 260 includes an individual pipe for each type of gas, an opening/closing valve provided midway on the individual pipe, and a flow rate controller provided midway on the individual pipe. When the opening/closing valve opens the individual pipe, a gas is supplied from the supply source to the gas supply path 261. The supply amount is controlled by the flow rate controller. On the other hand, when the opening/closing valve closes the individual pipe, the supply of the gas from the supply source to the gas supply path 261 is stopped.

Although the embodiments of the film formation method and the film formation device according to the present disclosure have been described above, the present disclosure is not limited to the above-described embodiments. Various changes, modifications, substitutions, additions, deletions, and combinations may be made within the scope defined in the claims. These also fall within the technical scope of the present disclosure.

This application claims priority based on Japanese Patent Application No. 2022-020187 filed with the Japan Patent Office on Feb. 14, 2022. The entire contents of Japanese Patent Application No. 2022-020187 are incorporated herein by reference.

### EXPLANATION OF REFERENCE NUMERALS

1: substrate, 1a: substrate surface, 11: insulating film (first film), 12: conductive film (second film), 17: SAM (Self-Assembled Monolayer)

1-11. (canceled)

12. A film formation method, comprising:
(A) preparing a substrate having a first film and a second film formed in different regions of a surface of the substrate, the second film made of a material different from the first film;
(B) supplying a gas of carboxylic acid or phosphonic acid to the surface of the substrate to selectively form a self-assembled monolayer on a surface of the second film relative to a surface of the first film; and
(C) forming a target film on the surface of the first film while inhibiting formation of the target film on the surface of the second film using the self-assembled monolayer, after (B),
wherein (C) includes (C1) supplying a precursor gas for the target film to the surface of the substrate, and (C2) supplying a gas of carboxylic acid or phosphonic acid as an oxidizing gas to the surface of the substrate.

13. The film formation method of claim 12, wherein a cycle including (B), (C1) and (C2) is performed repeatedly.

14. The film formation method of claim 13, further comprising:
(D) supplying a hydrogen-containing gas turned into plasma to the surface of the substrate to remove a carboxylic acid residue or a phosphonic acid residue adhering to the target film in (C1), after (C).

15. The film formation method of claim 14, wherein a cycle including (B), (C1), (C2) and (D) is performed repeatedly.

16. The film formation method of claim 13, wherein in (B) and (C2), the same gas of carboxylic acid or phosphonic acid is used.

17. The film formation method of claim 13, wherein the gas of carboxylic acid or phosphonic acid used in (C2) has a straight chain shorter than a straight chain of the gas of carboxylic acid or phosphonic acid used in (B).

18. The film formation method of claim 13, wherein a supply amount of the gas of carboxylic acid or phosphonic acid used in (C2) is smaller than a supply amount of the gas of carboxylic acid or phosphonic acid used in (B).

19. The film formation method of claim 13, wherein the carboxylic acid used in (B) includes at least one selected from the group consisting of CF3 (CF2)2COOH, CF3COOH, C6H5COOH and CH3(CH2)nCOOH (where n is an integer of 2 to 10).

20. The film formation method of claim 13, wherein the first film is an insulating film, and the second film is a conductive film.

21. The film formation method of claim 20, wherein the conductive film is a Cu film, a Co film, a Ru film, or a W film.

22. The film formation method of claim 12, further comprising:
(D) supplying a hydrogen-containing gas turned into plasma to the surface of the substrate to remove a carboxylic acid residue or a phosphonic acid residue adhering to the target film in (C1), after (C).

23. The film formation method of claim 12, wherein in (B) and (C2), the same gas of carboxylic acid or phosphonic acid is used.

24. The film formation method of claim 12, wherein the gas of carboxylic acid or phosphonic acid used in (C2) has a straight chain shorter than a straight chain of the gas of carboxylic acid or phosphonic acid used in (B).

25. The film formation method of claim 12, wherein a supply amount of the gas of carboxylic acid or phosphonic acid used in (C2) is smaller than a supply amount of the gas of carboxylic acid or phosphonic acid used in (B).

26. The film formation method of claim 12, wherein the carboxylic acid used in (B) includes at least one selected from the group consisting of CF3(CF2)2COOH, CF3COOH, C6H5COOH and CH3(CH2)nCOOH (where n is an integer of 2 to 10).

27. The film formation method of claim 12, wherein the first film is an insulating film, and the second film is a conductive film.

28. A film formation device, comprising:
a processing container;
a holder configured to hold a substrate inside the processing container;
a gas supply mechanism configured to supply a gas into the processing container;
a gas exhaust mechanism configured to exhaust the gas from the processing container;
a transfer mechanism configured to transfer the substrate into and out of the processing container; and
a controller configured to control the gas supply mechanism, the gas exhaust mechanism, and the transfer mechanism to perform the film formation method of claim 12.

29. A film formation device, comprising:
a processing container;
a holder configured to hold a substrate inside the processing container;
a gas supply mechanism configured to supply a gas into the processing container;
a gas exhaust mechanism configured to exhaust the gas from the processing container;
a transfer mechanism configured to transfer the substrate into and out of the processing container; and
a controller configured to control the gas supply mechanism, the gas exhaust mechanism, and the transfer mechanism to perform the film formation method of claim 13.
